(19) United States
(12) Patent Application Publication
(10) Pub. No.: US 2015/0292957 A1
(43) Pub. Date: Oct. 15, 2015

(54) METHOD, COMPUTER PROGRAM AND APPARATUS FOR MEASURING A DISTRIBUTION OF A PHYSICAL VARIABLE IN A REGION

(71) Applicant: Ecole Polytechnique Federale de Lausanne (EPFL), Lausanne (CH)

(72) Inventors: Juri RANIERI, Lausanne (CH); Amina CHEBIRA, Lausanne (CH); Martin VETTERLI, Grandvaux (CH)

(73) Assignee: Ecole Polytechnique Federale de Lausanne (EPFL), Lausanne (CH)

(21) Appl. No.: 14/248,984

(22) Filed: Apr. 9, 2014

(51) Int. Cl. G01K 13/00; G01R 31/28; G06F 17/16

(52) U.S. Cl. CPC G01K 13/00; G06F 17/16; G01R 31/2874

(57) ABSTRACT

Method for measuring a distribution of a physical variable in a region, comprising the step of:
measuring an average value of the physical variable along each of a plurality of lines in said region;
estimating the distribution of the physical variable in said region on the basis of the plurality of average values of the physical variable along the plurality of lines.

### FIELD OF THE INVENTION

The present invention concerns a method, a computer program and an apparatus for measuring a distribution of a physical variable in a region.

### DESCRIPTION OF RELATED ART

The continuous evolution of process technology enables the inclusion of multiple cores, memories and complex interconnection fabrics on a single die. Although many-core architectures potentially provide increased performance, they also suffer from increased IC power densities and thermal issues have become serious concerns in latest designs with deep submicron process technologies. In particular, it is key to design many-core designs that prevent hot spots and large on-chip temperature gradients, as both conditions severely affect system's characteristics, i.e., increasing the overall failure rate of the system, reducing performance due to an increased operating temperature, and significantly increasing leakage power consumption (due to its exponential dependence on temperature) and cooling costs.

Designers organize the floorplan to limit these thermal phenomena, for example, by placing the highest power density components closer to the heat sink. However, the workload execution patterns are fundamental to determine the transient on-chip temperature distribution in multicore designs and, unfortunately, these patterns are not fully known at design time. Furthermore, these issues are amplified in many-core designs, where thermal hot-spots are generated without a clear spatio-temporal pattern due to the dynamic task set execution nature, based on external service requests, as well as the dynamic assignment to cores by the many-core operating systems (OS).

Therefore, latest many-core designs include dynamic thermal management approaches that incorporate thermal information into the workload allocation strategy to obtain the best performance while avoiding peaks or large gradients of temperature.

The temperature map of a processor can be estimated by the solution of the direct problem, given the heat sources and the physical model of the temperature diffusion (e.g. a nonlinear diffusion equation). This approach is limited by its requirements: the knowledge of the heat sources can be ascribed to the knowledge of the detailed power consumption of the different components. This information is not usually known at runtime. Even if we can estimate this power distribution, the computation of a solution would require an excessive computational power.

Alternatively, the temperature distribution, mostly an instantaneous temperature map, of a processor can be estimated by the solution of the inverse problem, given the value of the temperature in some locations and some a-priori information about the temperature map.

US2013/0151191 discloses to use the temperature at some locations on the temperature map, to estimate from the measurements coefficients of an optimal subspace constructed on the basis of the eigenvectors of the covariance matrix of the vectorized temperature map relating to the largest eigenvalues and to determine the temperature map on the basis of the known vector transformation from the subspace to the vector space of the temperature map. However, this approach has the disadvantage that number of measurements needed rise with the noise level of the measurements. Therefore, either few expansive sensors for low noise measurements are used or a high number of sensors must be used in order to determine a good estimator for the temperature map.

This problem arises with each reconstruction of a distribution of a physical variable from a subset of measurements of said distribution.

### BRIEF SUMMARY OF THE INVENTION

Therefore, it is an object of the invention to provide a method, a computer program and an apparatus for estimating a distribution of a physical variable from a subset of measurements of said distribution.

This object is achieved by the method, computer program and apparatus according to the independent claims.

Especially, the measurement of an average value of the physical variable along each of a plurality of lines in a region of said distribution is more stable to process variations than measurement points and the results seem to be much more stable against measurement noise.

The dependent claims refer to further embodiments of the invention.

In one embodiment, a wire is arranged along each line in said region and the average value of the physical variable along each line is measured by measuring a wire characteristic over the wire arranged along the corresponding line. Wires have the big advantage that they can easily be placed almost everywhere and that they do not occupy much space. Sensors on the other hand need much space and they cannot be positioned everywhere. E.g. on chips the sensor placement is only possible in some regions of the chip. For a wire, there are no such restrictions.

In one embodiment, the wire is an optical wire, e.g. an optical fibre.

In one embodiment, the wire is an electrical wire.

In one embodiment, the average value of the physical variable along each of the plurality of lines is measured on the basis of a measuring device transported during the measurement of said physical variable along said line.

In one embodiment, the physical variable is the temperature.

In one embodiment, the region is a chip, an apparatus, a room or a building.

In one embodiment, the distribution of the physical variable in said region is described by a vector for the distribution of the physical variable, wherein the step of estimating the distribution of the physical variable is based on a subspace vector defining a subspace of the vector space of the vector for the distribution of the physical variable in said region, wherein the subspace vector is estimated on the basis of the plurality of average values of the physical variable along the plurality of lines.

In one embodiment, the subspace vector relates to the subspace of the vector space for the distribution of the physical variable relating to a number of eigenvectors with the largest eigenvalues.

In one embodiment, the step of estimating the distribution of the physical variable in said region comprises estimating the vector for the distribution of the physical variable on the basis of a basis vector transformation of the subspace vector.

In one embodiment, the step of estimating said subspace vector is performed on the basis of the inverse or pseudo inverse of a matrix being based on said basis vector transformation and a line arrangement matrix defining for each line the positions of said line in the vector space for the distribution of the physical variable.

In one embodiment, the step of estimating the subspace vector is based on a matrix defining for each line the positions of said line in the vector space for the distribution of the physical variable.

In one embodiment, the distribution of the physical variable is a two-dimensional field of the physical variable.

In one embodiment, the distribution of the physical variable is a three-dimensional field of the physical variable.

All the embodiments described above can be combined.

### BRIEF DESCRIPTION OF THE DRAWINGS

The invention will be better understood with the aid of the description of an embodiment given by way of example and illustrated by the figures, in which:

FIG. 1 shows a simplified floorplan of a chip;

FIG. 2 shows indices of a temperature map for the chip;

FIG. 3 shows the prior art arrangement of sensors on the chip of FIG. 1;

FIG. 4 shows the prior art measurement position matrix;

FIG. 5 shows an embodiment of an arrangement of sensors measuring an average value of a physical variable along a line;

FIG. 6 shows an embodiment of a measurement position matrix for measurements of a physical variable along different lines;

FIG. 7 shows the steps performed online of one embodiment of the method for estimating the distribution vector;

FIG. 8 shows steps performed offline of one embodiment of the method for estimating the distribution vector; and

FIG. 9 shows an embodiment of an apparatus for determining a distribution of a physical variable.

### DETAILED DESCRIPTION OF POSSIBLE EMBODIMENTS OF THE INVENTION

The invention refers to estimating a distribution of a physical variable in a region. A region can be a geographical region like a continent, a country or other geographical regions, a region of an apparatus like a chip, a computer or a machine, a region of a room or a building like a server room or a server hall or other regions. Physical variables can be a temperature, a variable indicating a pollution, a variable indicating a radioactivity, a variable indicating a rain fall or any other physical variable distributed over a field. A distribution (also called field) can be a two dimensional field like the surface of a geographical region or of a chip or can be three-dimensional field like in the case of three-dimensional integrated circuits or in three-dimensional packaging of integrated circuits.

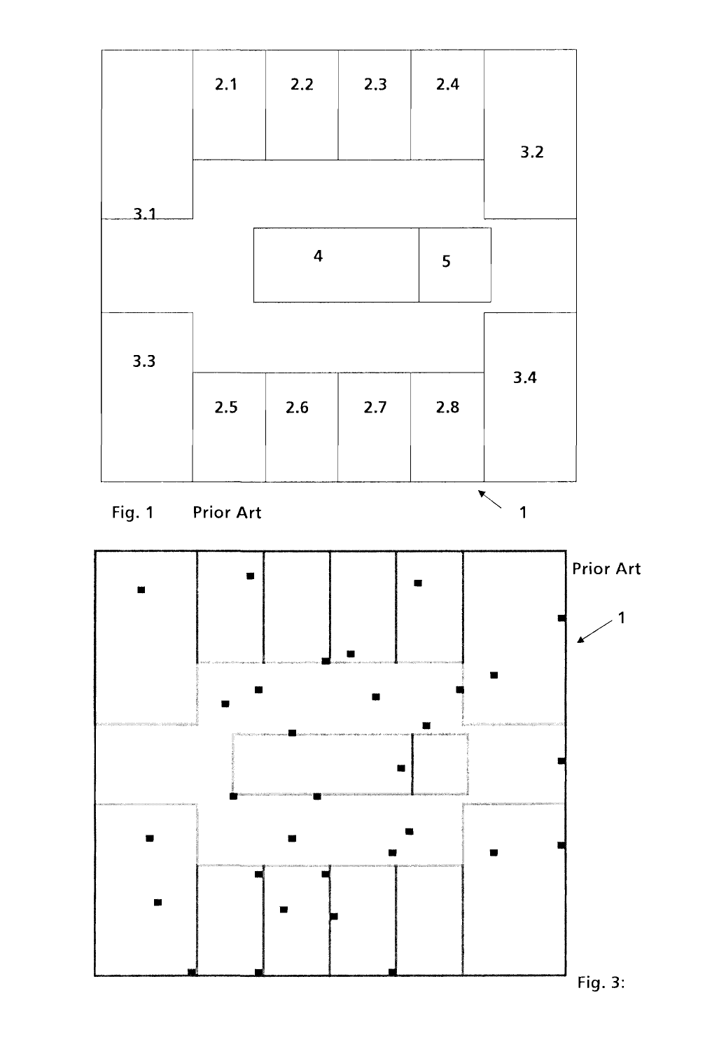

FIG. 1 shows a floorplan of a chip 1 according to one exemplary region for estimating the temperature map on said chip 1 as a distribution of a physical variable. In this embodiment the chip 1 is an 8-core processor comprising eight cores 2.1 to 2.8, four Level 2 caches 3.1 to 3.4, a crossbar 4 and a floating point unit (FPU) 5. It is obvious that chip 1 is much more complex than shown and comprises more parts than mentioned. The chip 1 shown in FIG. 1 has different temperature distributions depending on several parameters like the actual workload, the ambience temperature, the power of the cooling, etc.

Before describing the methods and apparatuses according the embodiments of the invention, the model for estimating the temperature distribution of the chip 1 is presented.

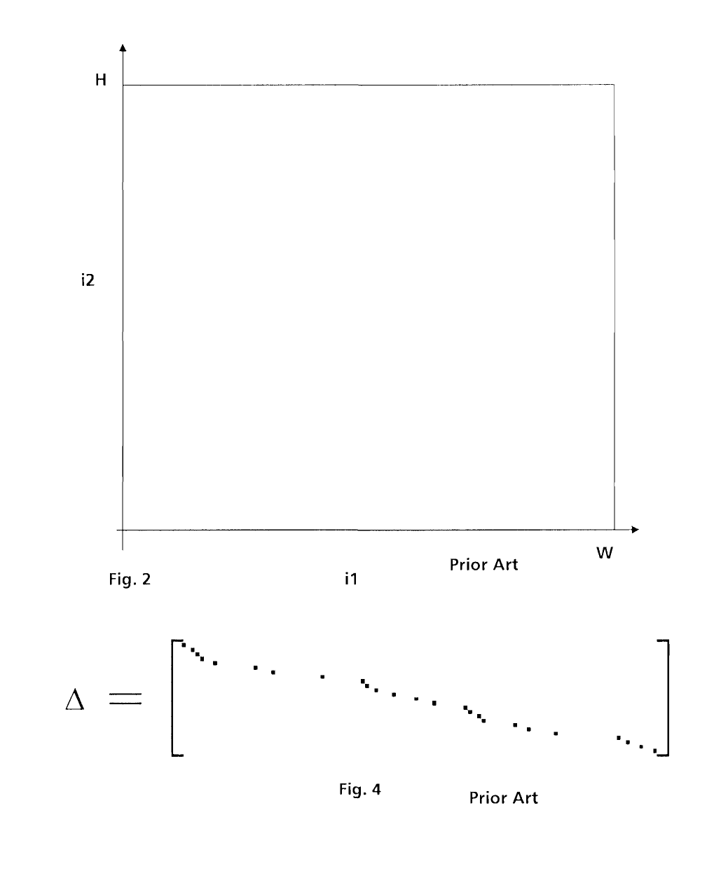

In order to describe the temperature distribution of the chip 1, a discretized temperature map l is defined as shown in FIG. 2. The temperature at coordinates i1 and i2 is defined as t[i1, i2] for 0≦i1≦H−1 and 0≦i2≦W−1. Where W and H are the width and the height of the discretized temperature map, respectively. The temperature map is vectorized as x[i], for 0≦i≦N−1 and N=WH, that is

$$x [ i ] = t [ i mod H . ⌊ \frac{i}{W} ⌋ ] . \qquad ( 1 )$$

In other words, the columns of the discrete thermal map are stacked to transform the matrix t into a vector x. Preferably, the natural numbers H and W are chosen such that the geometry of the surface of the chip 1 is covered by equidistant coordinates and that the existence of temperature variations between two neighbouring coordinates is excluded. However, it is understood that any coordinate system can be chosen. For example the regions prone to higher thermic stress, e.g. regions with higher temperature and/or regions with more complex and irregular temperature spreading patterns and/or regions with higher temperature gradients, could include a more dense net of coordinates than the remaining regions on the chip or on the respective region in other embodiments. For three-dimensional regions, the three-dimensional array of points of the distribution of the corresponding physical variable will be vectorized accordingly.

The considered mathematical model is similar to the one derived in US2013/0151191, where the temperature of the chip, of the server room or any other distribution of a physical variable is defined as an N-dimensional vector x, where N is the resolution of the distribution of the physical variable. The vector x is modelled by a linear K-dimensional subspace that is spanned by a matrix Φ with N rows and K columns as,

$$\hat{\dot{x}} = [ \begin{matrix}\hat{x} [ 0 ] \\ ⋮ \\ \hat{x} [ N ]\end{matrix} ] = [ \begin{matrix}Φ [ 0 , 0 ] & … & Φ [ 0 , K - 1 ] \\ ⋮ & ⋱ & ⋮ \\ Φ [ N - 1 , 0 ] & … & Φ [ N - 1 , K - 1 ]\end{matrix} ] [ \begin{matrix}α [ 0 ] \\ ⋮ \\ α [ K - 1 ]\end{matrix} ] = Φ {α}^{\_ \cdot } \qquad ( 1 )$$

where \vec{α} is the K-dimensional parametrization of the vector x, i.e. a subspace vector \vec{α}. In other words, it is assumed that the N-dimensional vector x can be represented with only K linear parameters.

In one embodiment, the dimension K is equal or lower than the dimension N. In one embodiment, the matrix Φ is constructed by K basis vectors, wherein preferably, the K basis vectors correspond to another basis system than the Cartesian basis system of the vector x. In one embodiment, the K basis vectors are chosen on the basis of the eigenvectors of the covariance matrix of the random vector x. In one embodiment the K-eigenvectors with the largest eigenvalues are chosen as columns for the matrix Φ. The eigenvectors and the corresponding eigenvalues can be determined on the basis of the covariance matrix Cₓ that is defined for real zero-mean random variables as

Cₓ[i,j]=E[x[i],x[j]].

For non-zero-mean random variables, the covariance matrix must be corrected accordingly. The covariance matrix can be determined for the vector x on the basis of a plurality of realizations of the vector x. These realizations can be captured by actual measurements or by a simulation of the system. Details about the determination of the matrix (base transformation) Φ are described in US2013/0151191 which is hereby incorporated by reference. However, the invention is not restricted to this subspace. Any other subspace can be determined in order to define the matrix Φ. It is also possible to use a subspace with K=N, but preferably K is smaller N.

In US2013/0151191, there are placed M sensors for measuring the physical variable in the region of interest. In FIG. 3, M sensors are placed on the chip 1 to measure the temperature as a physical variable. The M sensors are indicated by black rectangles on the chip 1. In order to estimate the subspace vector \vec{α}, the M rows indicated of the matrix Φ corresponding to the positions of the M sensors in the vector x construct the matrix Φ_{M} with M rows and K columns. Therefore, the physical variable at the M sensor positions are determined by

$${\ddot{x}}_{M} = [ \begin{matrix}\hat{x} [ m ( 0 ) ] \\ ⋮ \\ \hat{x} [ m ( M - 1 ) ]\end{matrix} ] = [ \begin{matrix}Φ [ m ( 0 ) , 0 ] & … & Φ [ m ( 0 ) , K - 1 ] \\ ⋮ & ⋱ & ⋮ \\ Φ [ m ( M - 1 ) , 0 ] & … & Φ [ m ( M - 1 ) , K - 1 ]\end{matrix} ] [ \begin{matrix}α [ 0 ] \\ ⋮ \\ α [ K - 1 ]\end{matrix} ] = {Φ}_{M} \dot{α} , \qquad ( 2 )$$

with \vec{x}_{M} being a realization of the M-dimensional vector of the physical variable for the M measurement positions and with m(i) with i≈0, . . . M−1 indicating the index of the vector x relating to the i-th sensor. Therefore, the subspace vector \vec{α} can be estimated by the inverse of the matrix Φ_{M} and by the measurement vector \vec{x}_{M}

{right arrow over (\hat{α}=Φ_{M}⁻¹\vec{x}_{M} (3)

where the hat over a variable indicates an estimate of such variable. Finally, the vector x can be estimated using equations (1) and (3)

{right arrow over (\hat{x}=Φ{right arrow over (\hat{α}=ΦΦ_{M}⁻¹\vec{x}_{M}. (4)

Normally, the inverse is a pseudo inverse, if the M is not equal to N. However for the exceptional case, if M=N also the standard inverse can be used. If a measurement position matrix Δ_{M} is defined, the matrix Φ_{M} can be described by

ΦΔ_{M}=Δ_{M}Φ, (5)

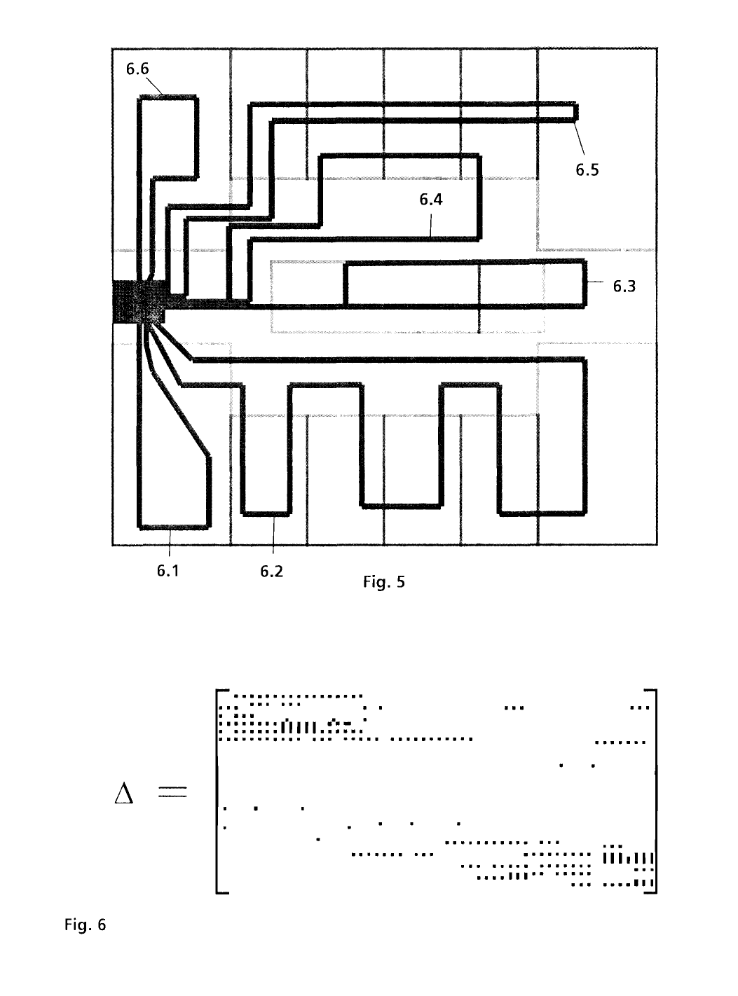

with Δ_{M} being the sparse matrix with N columns and with M rows, wherein the i-th row comprises only zeros except at the m(i)-th position, i.e. at the index corresponding to the i-th sensor or the i-th measurement position. FIG. 4 shows such a realization of a sparse matrix for 25 measurement points and a 112 dimensional vector x. The black points refer to the 25 ones in the sparse matrix.

However, as mentioned in the introduction this approach has the disadvantage that due to the measurement error of the sensors high precision sensors or measurements are needed and/or a high number of sensors is needed.

The present invention thus suggests to measuring an average value of the physical variable along L lines in the region of the distribution of the physical variable instead of only at a plurality of individual points. Therefore, even simple and low-complexity sensors can be used in order to measure the physical variable, because the accumulation over the complete line reduces the measurement error and the physical variable is not only determined for one single coordinate of the vector x.

FIG. 5 shows an example of chip 1 as a region of a distribution of a physical variable provided with six (L=6) wires arranged within the region of chip 1. As a physical variable the temperature shall be estimated. However, the following invention can be used for any physical variable appearing in a distribution over a region and for any kind of region.

In order to compute the matrix Φ_{L}Δ_{L}Φ, the measurement position matrixΔ_{L} now defines for each line l=1, . . . , L (here a wire l) a row indicating the arrangement of the corresponding line in the region. In one embodiment for the l-th line (l-th wire) with l=1, . . . , L, the l-th row comprises a one for each of the N-position of the vector x which are covered and/or touched by the l-th line and a zero for the other positions of the vector x not being covered and/or touched by the l-th line. The measurement position matrix Δ_{L} is therefore a matrix with L rows and with N columns. FIG. 6 shows such a realization of a measurement position matrix Δ_{L} for 50 lines (L=50) and a 112-dimensional vector x (N=112). The black points refer to the ones in the sparse matrix of zeros. The vector x can thus be estimated on the basis of the measurement of the physical variable along L lines resulting in the L-dimensional measurement vector \vec{x}_{L}. The vector x can thus be estimated by the equation

{right arrow over (\hat{x}=Φ(Δ_{L}Φ)⁻¹\vec{x}ₖ, (6)

A line in the sense of the invention is a plurality of indices of the vector x. In one embodiment, the plurality of indices of the vector x refers to points which define a continuous line in the region of the distribution of the physical variable. In one embodiment, the line can cover a two-dimensional plane such that the physical variable of the line is measured by an average characteristic of said plane, e.g. of an electrical or optical plate. In one embodiment, the line can also cover a three-dimensional block. Line in the sense of the invention can cover straight lines as well as any other line forms like curves, angles, etc.

The arrangement of the L lines in the region of the distribution of the physical variable can be determined by defining a large number O>L of possible line arrangements which evtl. must fulfil some technical constraints. The arrangements could be deterministic or random arrangements. The matrix Δ_{O} with the O rows for the O line arrangements is constructed. The submatrix Δ_{L} is obtained by the L rows of the matrix Δ_{O} corresponding to the L rows of the matrix Δ_{O}Φ creating the submatrix Δ_{L}Φ with minimal rank. One algorithm for estimating the matrix Δ_{L}Φ with minimal condition number is to remove repeatedly the lines of Δ_{O}Φ comprising the maximum off-diagonal element until only L rows remain. Details about this algorithm are described in US2013/0151191 which is hereby incorporated by reference. However, also other algorithms are known and can be used.

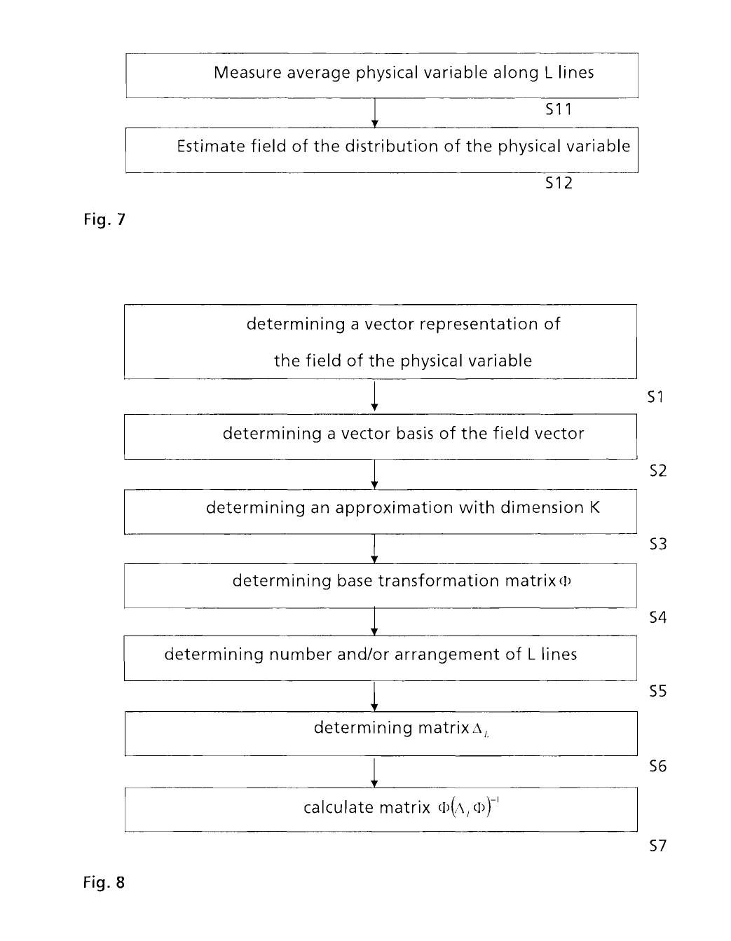

FIG. 7 shows the steps of the method according to the invention. In step S11 an average value of a physical variable is measured along each of L different lines. In step S12, the distribution of the physical variable, i.e. the vector x, is estimated on the basis of the measurements of S11.

FIG. 8 shows the steps for preparing the estimation of the vector x in step S12. In step S1, the region of interest is covered by N distributed sampling points. Those N sampling positions are vectorized in an N-dimensional vector x. In step S2, a vector basis of the vector x is determined, preferably but without any restriction of the invention not a Cartesian vector basis, even more preferably but without any restriction of the invention, the vector basis is chosen on the basis of the Eigenvectors of the covariance matrix of the random vector x. In step S3, a subspace of the vector space of the vector x is created such that the vector x can be described by a subspace vector. Preferably but without any restriction of the invention, the subspace of the K Eigenvectors of said covariance matrix corresponding to the K largest Eigenvalues are chosen as subspace. In step S4, a base transformation matrix Φ for transforming the subspace vector into the vector space of the vector x is determined. In step S5, a number and/or an arrangement of the L lines in the region of the distribution of the physical variable is determined. In step S6, the measurement position matrix Δ_{L} is defined according to the arrangement of the L lines. In step S7, the matrix Φ(Δ_{L}Φ)⁻¹ is calculated which is according to equation (6) used to determine the vector x from the vector of the L measurements. For some applications where the number and/or arrangement of the measurement lines change over time, the steps S5 to S7 are performed online during step S12.

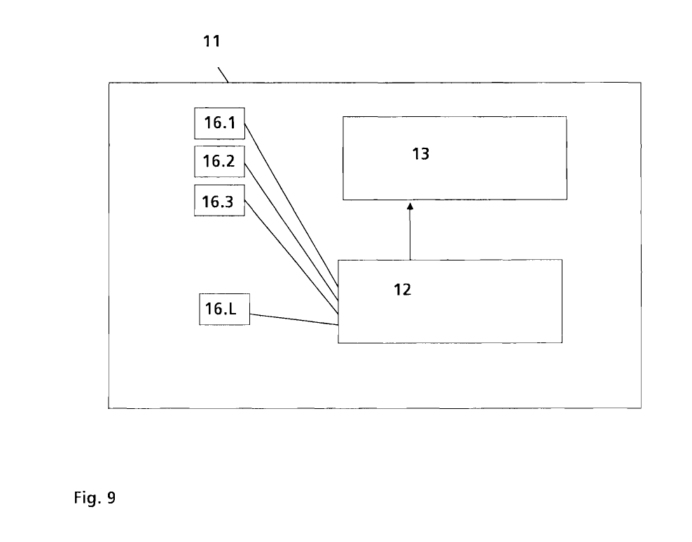

FIG. 9 shows an embodiment of an apparatus 11 for determining a distribution of a physical variable. The apparatus comprises a sensor 12 and an estimator 13. The sensor 12 receives the measurements of the physical variable along the L lines 16.1, 16.2, 16.3, . . . , 16.L. The estimator 13 estimates the distribution of the physical variable on the basis of the measurements from the sensor 12.

In the following different embodiments are presented.

Knowledge of the temperature distribution over time is fundamental for the development of new many-cores architectures. An example of such an architecture is given in FIGS. 1 and 5. Generally, temperature is sensed locally using thermistors—transistors that are very sensitive to temperature variations—and an analog-to-digital interface. The quality of the reconstruction of the thermal map depends on the number of sensors, their locations and the amount of noise. It is now proposed a new sensing paradigm where the sensors are not the thermistors anymore, but the wires themselves. Preferably, electrical wires are used whose resistance is sensible to the temperature. However, also optical wires could be used whose parameters (like the luminosity) depend on the temperature. Examples of optical wires are optical fibres. For the estimation of the thermal map of a chip, an apparatus, any machine, a room, etc. the following steps are performed. The wires can be considered as probes which slightly change the resistance according to their temperature. Each wire computes an integral of the temperature of the microprocessor or any other region of interest. The resistance of each wire can be determined by a classical setup like an operational amplifier and an analog-to-digital converter. These measurements are used to recover the low-dimensional approximation in the EigenMaps space (Eigenvector space), using a simple matrix multiplication at run-time. Alternatively any other subspace can be used. However, the EigenMaps space is considered the optimal subspace. This approach has many advantages: Just one resistance sensor can be used for many wires to sense the temperature in many locations. E.g. the resistance of different wires can be determined sequentially with the same sensor. With this information the entire distribution of temperature map can be recovered. The single sensor can occupy more area and have higher precision, rejection to noise and resolution. Even if the single wire has a lower sensitivity to the temperature than the traditionally used thermistor, i.e. the resistance varies less with temperature, it can be measured more precisely with a larger sensor. To increase the reconstruction performance, more wires can be used than sensors given the reduced area occupation of a wire compared to a sensor. The use of wires instead of point sensors is that wires are much easier to place and they need much less space.

Another embodiment is an estimation of the temperature map for a server room. The knowledge of the temperature is necessary to optimize the cooling, that is responsible in large part of the cost of a server. In one embodiment, a set of ultrasound microphones and speakers can be used to measure integrals of the speed of sound along particular trajectories. The speed of sound depends linearly on the temperature of the dielectric, allowing us to recover the room temperature distribution from a sufficient number of measurements.

Another embodiment is pollution monitoring. Many types of sensors used for pollution monitoring require a few minutes to deliver a measurement. Many private/public sensor networks considered the use of these sensors on mobile structures, such as buses and taxis. One of the classical issues regards how to obtain spatially localized measurements with very low sampling frequencies and moving sampling trajectories. Solutions are many and mostly mechanical, such as sniffing boxes. These boxes enclose the sensor and allow the following sampling scheme: they pump some air inside and they seal the environment inside the box from the external one, then the sensors sense the quantities of interest, and the cycle is concluded by a flushing. This cycle is repeated with a frequency bounded from above by the speed of the sensors. By using a naked sensors, this monitoring scheme can be simplified by using the present invention. The region could be a geographical region like a town and the sensors could be mounted on moving objects like vehicles, public transport, etc. Thus, the movement of the object in the geographical region during one measurement cycle corresponds to the above defined line. This line can be used to define the row of the measurement position matrix Δ_{L}. The pollution of the geographical region can be determined by a number of such measurements within a certain time period, wherein the measurement position matrix Δ_{L} is continuously adapted to the corresponding measurement lines. Using this approximation and the integration over the trajectories, it can be avoided to obtain spatially localized measurements that represent a cost for the sensor network and are partially responsible for the ill-conditioning of the inverse problem.

A similar embodiment is the measurement of radioactivity with Geiger counter which counts the number of events within a certain time period. Those Geiger counter could be mounted on moving objects in order to detect the average radioactivity along the trajectory of the moving object during the certain time period.

Another embodiment of the present invention is rain analysis from river measurements. The rain distribution r(x,y) in a region shall be estimated by measuring the increment of water transported by the many rivers and channels that are lying in that region. The increment of water yin a river n is on a first approximation the amount of rain falling over the river that has a path C. Again, even if the number of rivers is limited, we can estimate the rain distribution. If we know a low-dimensional subspace this estimation could achieve a higher resolution and precision. This low-dimensional subspace could be estimated at design time using numerical simulations based on the environmental model of the zone of interest.

A similar scenario can be envisioned for the pollution dispersion in a sewer or channel network.

The invention is not limited to the described embodiments. All embodiments falling under the scope of the claims shall be protected.

1. Method for measuring a distribution of a physical variable in a region, comprising the step of:
measuring an average value of the physical variable along each of a plurality of lines in said region;
estimating the distribution of the physical variable in said region on the basis of the plurality of average values of the physical variable along the plurality of lines.

2. Method according to claim 1, wherein a wire is arranged along each line in said region and the average value of the physical variable along each line is measured by measuring a wire characteristic over the wire arranged along the corresponding line.

3. Method according to claim 2, wherein the wire is an optical wire.

4. Method according to claim 2, wherein the wire is an electrical wire.

5. Method according to claim 1, wherein the average value of the physical variable along each of the plurality of lines is measured on the basis of a measuring device moved during the measurement of said physical variable along said line.

6. Method according to claim 1, wherein the average value of the physical variable along each of the plurality of lines is measured by measuring a physical variable of a moving fluid at a plurality of positions of the moving fluid, wherein the moving fluid flows at least above the measurements positions along predetermined movement lines.

7. Method according to claim 1, wherein the physical variable is the temperature.

8. Method according to claim 1, wherein the region is a chip, an apparatus, a room or a building.

9. Method according to claim 1, wherein the distribution of the physical variable in said region is described by a distribution vector, wherein the distribution vector is estimated on the basis of a subspace vector defining a subspace of the vector space of the distribution vector, wherein the subspace vector is estimated on the basis of the plurality of average values of the physical variable along the plurality of lines.

10. Method according to claim 9, wherein the subspace vector relates to the subspace of the vector space for the distribution vector based on a number of eigenvectors of a covariance matrix of the distribution vector corresponding to the largest eigenvalues.

11. Method according to claim 9, wherein the distribution vector is estimated on the basis of a basis vector transformation of the subspace vector.

12. Method according to claim 11, wherein the step of estimating said subspace vector is performed on the basis of the inverse or pseudo inverse of a matrix being based on said basis vector transformation and a line arrangement matrix defining for each line the positions of said line in the vector space for the distribution of the physical variable.

13. Method according to claim 9, wherein the step of estimating the subspace vector is based on a matrix defining for each line the positions of said line in the vector space for the distribution of the physical variable.

14. Method according to claim 9, wherein the dimensional distribution vector {right arrow over (\hat{x} is estimated by {right arrow over (\hat{x}={right arrow over (\hat{α}(Δ_{L}Φ)⁻¹\vec{x}_{L}, wherein Φ is a K×N matrix comprising K basis vectors as columns, Δ_{L} is the L×N matrix defining for each of the L lines the positions of said line in the vector space for the distribution of the physical variable and \vec{x}_{L} is the L dimensional vector of measured average values along the L lines.

15. Method according to claim 1 comprising at least one sensor for measuring the physical variable at at least one position and estimation the distribution of the physical variable on the basis of the plurality of average values of the physical variable along the plurality of lines and the at least one measurement of the at least one sensor.

16. Computer program for measuring a distribution of a physical variable in a region, configured to perform the following steps when executed on a processor:
measuring an average value of the physical variable along each of a plurality of lines in said region;
estimating the distribution of the physical variable in said region on the basis of the plurality of average values of the physical variable along the plurality of lines.

17. Apparatus for measuring a distribution of a physical variable in a region, comprising:
a sensor for measuring an average value of the physical variable along each of a plurality of lines in said region;
an estimator for estimating the distribution of the physical variable in said region on the basis of the plurality of average values of the physical variable along the plurality of lines.

18. Apparatus according to claim 17, wherein the estimator is configured to describe the distribution of the physical variable in said region by a distribution vector and to estimate a subspace vector on the basis of the plurality of average values of the physical variable along the plurality of lines, wherein the subspace vector lies in a subspace of the vector space of the distribution vector.

19. Apparatus according to claim 18, wherein the subspace vector relates to the subspace of the vector space for the distribution vector based on a number of eigenvectors of a covariance matrix of the distribution vector corresponding to the largest eigenvalues.

20. Apparatus according to claim 18, wherein the estimator is configured to estimate the distribution vector on the basis of a basis vector transformation from the subspace vector to the distribution vector.

21. Apparatus according to claim 20, wherein the estimator is configured to estimate said subspace vector on the basis of the inverse or pseudo inverse of a matrix being based on said basis vector transformation and a line arrangement matrix defining for each line the positions of said line in the vector space for the distribution of the physical variable.

22. Apparatus according to claim 18, wherein the estimator is configured to estimate the subspace vector on the basis of a matrix defining for each line the positions of said line in the vector space for the distribution of the physical variable.

23. Apparatus according to claim 18, wherein the estimator is configured to estimate the N-dimensional distribution vector {right arrow over (\hat{x} is estimated by {right arrow over (\hat{x}Φ(Δ_{L}Φ)⁻¹\vec{x}_{L}, wherein Φ is a N×K matrix comprising K basis vectors as columns, Δ_{L} is the L×N matrix defining for each of the L lines the positions of said line in the vector space for the distribution of the distribution of the physical variable and \vec{x}_{L} is the L dimensional vector of measured average values along the L lines.

24. Electronic apparatus comprising
a plurality of wires arranged in a region of the electronic apparatus;
a sensor for measuring an average value of the physical variable along each of the plurality of wires in said region;
an estimator for estimating a distribution of the physical variable in said region on the basis of the plurality of average values of the physical variable along the plurality of wires.
